(19) United States
(12) Patent Application Publication
(10) Pub. No.: US 2024/0381798 A1
(43) Pub. Date: Nov. 14, 2024

(54) RESISTIVE MEMORY CELL

(71) Applicants: COMMISSARIAT A L'ENERGIE ATOMIQUE ET AUX ENERGIES ALTERNATIVES, PARIS (FR); CENTRE NATIONAL DE LA RECHERCHE SCIENTIFIQUE, PARIS (FR); UNIVERSITE GRENOBLE ALPES, SAINT MARTIN D'HÈRES (FR); INSTITUT POLYTECHNIQUE DE GRENOBLE, GRENOBLE (FR)

(72) Inventors: Leo LABORIE, GRENOBLE CEDEX 09 (FR); Rachid HIDA, GRENOBLE CEDEX 09 (FR); Eric JALAGUIER, GRENOBLE CEDEX 09 (FR); Gauthier LEFEVRE, GRENOBLE CEDEX 09 (FR); Gabriele NAVARRO, GRENOBLE CEDEX 09 (FR); Killian VEYRET, GRENOBLE CEDEX 09 (FR); Xavier ZUCCHI, GRENOBLE CEDEX 09 (FR); Romain BON, GRENOBLE CEDEX 09 (FR)

(21) Appl. No.: 18/659,428

(22) Filed: May 9, 2024

(30) Foreign Application Priority Data
May 9, 2023 (FR) 2304573

(51) Int. Cl. H10N 70/00; H10B 63/00

(52) U.S. Cl. CPC H10N 70/8833; H10B 63/82; H10N 70/026; H10N 70/841; H10N 70/8613

(57) ABSTRACT

A resistive memory cell includes a lower electrode based on one of the following materials: titanium nitride TiN, tantalum nitride TaN, tantalum Ta, copper Cu, tungsten W, platinum Pt, gold Au or silver Ag, an upper electrode, an active layer having a first contact surface with the lower electrode and a second contact surface with the upper electrode, the active layer including a zone, referred to as the local zone, the local zone being made of a material including vanadium, oxygen and Ti or Ta or Cu or W or Pt or Au or Ag, the local zone extending from the first contact surface, the rest of the active layer being made of conductive vanadium oxide.

### CROSS-REFERENCE TO RELATED APPLICATIONS

This application claims priority to French Patent Application No. 2304573, filed May 9, 2023, the entire content of which is incorporated herein by reference in its entirety.

### FIELD

The technical field of the invention is that of resistive memories. The present invention relates to a non-volatile resistive memory cell.

### BACKGROUND

Non-volatile memories of the EEPROM or FLASH type are conventionally used for applications requiring information to be stored even when the voltage is switched off. However, these memories have drawbacks such as long write times, a density of memory points limited by the size of the transistors used and a limited number of rewrite cycles.

More recently, non-volatile resistive memories are a promising alternative to FLASH or EEPROM type memories.

Resistive memories are based on the use of an active medium whose electrical resistance depends on the electrical voltage applied across the material. In other words, a resistive memory cell has two states: an HRS state (‘High Resistive State’) and an LRS state (‘Low Resistive State’). The active medium is inserted between two electrodes allowing the application of an electrical voltage and ensuring the reading and writing of the state of the resistive memory cell.

According to the type of active material used, different types of resistive memory can be made: phase change materials (PCRAM or ‘Phase Change RAM’ also known as PCM or ‘Phase Change Memory’), ion conduction materials (CBRAM or ‘Conductive Bridging RAM’), metal oxide materials (OxRAM or ‘Oxide Resistive RAM’), magnetic materials (MRAM or ‘Magnetic RAM’), spin transfer torque magnetic materials (STTRAM or ‘Spin Torque Transfer RAM’) or Mott insulators.

So-called ‘Mott’ memories are based on the use of an active layer made of Mott insulating materials which, according to the band theory, should be conductive, but in reality are insulating due to strong electronic correlations. It is possible to make the material transition from this Mott insulating state to a metallic state by applying pressure or an electric field. In Mott memories, a SET voltage applied to the memory electrodes makes it possible to control the transition from the insulating state to the metallic state and a RESET voltage applied to the memory electrodes makes it possible to control the transition from the metallic state to the insulating state. It should be noted that Mott memories are of the apolar type: in other words, the sign of the SET or RESET voltage applied is irrelevant, unlike resistive memories of the bipolar type such as CBRAM memories, for example, for which it is necessary to invert the sign of the potential applied to the electrodes according to whether a SET or RESET operation is sought.

Among Mott insulators, crystallised vanadium sesquioxide in which some of the vanadium atoms are substituted with chromium, for example (V₁₋xCrₓ)₂O₃ (with x≥0.011), is a Mott insulator in which the phenomenon of reversible resistive switching induced by an electrical pulse is possible. It is therefore used to make Mott memories. The advantage of Mott resistive memories over other RRAM resistive memories is that they are based solely on electronic transition phenomena. Unlike some other resistive memories with an initial state in which the active material of the active storing zone is insulating (pristine state), the Mott memory does not require an initialisation step (that is, a step during which a first electrical stress therefore has to be applied to the blank memory cell in order to generate the LRS state for the first time).

Making thin layers of crystallised (V₁-xCrₓ)₂O₃ (with x≥0.011) which can be used in a Mott memory has been obtained by Physical Vapour Deposition (PVD) techniques such as magnetron cathode sputtering: to do this, vanadium- and chromium-based targets are abraded by argon ions under oxygen pressure in order to obtain an amorphous vanadium oxide which is not stoichiometric in oxygen and chromium. But the material (V₁-xCrₓ)₂O₃ (with x>0.011) used in Mott memories has to be crystallised and perfectly stoichiometric. Accordingly, the PVD deposition step is followed by an annealing step at a temperature greater than or equal to 500° C. in a reducing atmosphere. Such a technique has some drawbacks in a back-end CMOS integration logic in which the thermal budget should not exceed 450° C.

### SUMMARY

An aspect of the invention provides a solution to the problems discussed previously, by providing a vanadium oxide-based non-volatile resistive memory cell which is especially easier to integrate into a CMOS back end process.

By resistive memory cell, it is meant an electrical device having a first high resistive state or HRS state or RESET state and a second low resistive state or LRS state or SET state. The non-volatility resides in the fact that the memory cell retains its resistive state once the SET or RESET voltage is no longer applied.

More specifically, an aspect of the invention is a resistive memory cell including:
A titanium nitride-based lower electrode,
An upper electrode,
An active layer having a first contact surface with the lower electrode and a second contact surface with the upper electrode, the active layer including a zone, referred to as the local zone, the local zone being of a material including vanadium, titanium and oxygen extending from the first contact surface, the rest of the active layer being made of conductive vanadium oxide V₂O₃.

By conductive vanadium oxide V₂O₃, it is meant a V₂O₃ material with a resistivity less than or equal to 0.1 ohm.cm.

Unlike Mott memories, which are based on the use of a (V₁-xCrₓ)₂O₃ material (with x>0.011) in the Mott insulator phase, the memory cell according to an aspect of the invention uses an active layer mainly made of V₂O₃ with a singular zone in this layer at the interface between the active layer and the lower electrode: this zone in the active layer at the lower electrode is not made of conductive vanadium oxide V₂O₃ and includes a high resistive material including vanadium, titanium and oxygen. Surprisingly, the applicant found that such a cell had a resistive memory operation enabling it to switch between a high resistive HRS state and a low resistive LRS state. These RESET and SET operations are carried out by applying a potential difference of opposite polarity between the upper and lower electrodes of the memory cell: in other words, unlike Mott memories, the cell according to an aspect of the invention has bipolar operation.

Surprisingly, the applicant has discovered the operation of the invention when wanting to make an insulating V₂O₃ material for a Mott memory using an IBD (Ion Beam Deposition) technique; by using this deposition technique, the inventors have obtained a conductive V₂O₃ material and therefore not adapted to a Mott memory known in the state of the art. However, by performing RESET/SET cycle operations on a stack including a conductive V₂O₃ active layer as deposited between two electrodes, the inventors have noticed a resistive memory type operation. They have also noticed that, during the first initialisation operation, the conductive V₂O₃ layer transitioned from a low resistive LRS state to a high resistive HRS state with the appearance of this singular high resistive local zone based on titanium, oxygen and vanadium in the V₂O₃ layer. This particular cell structure, including this zone formed from a V—Ti—O alloy, gives the cell according to an aspect of the invention the role of a bipolar resistive memory cell. The structure of this cell, its operation and the mechanism for creating this localised V—Ti—O zone, which is probably linked to strong heating at the interface between the lower electrode and the active layer during the initialisation step, will be described later. It should be noted that IBD deposition techniques enable crystalline or partially crystalline conductive V₂O₃ layers to be made at crystallisation temperatures greater than 280° C., thus perfectly compatible with CMOS back end integration.

It should be noted that the terms ‘lower’ and ‘upper’ are used for a better understanding of the invention but remain relative so that the lower electrode can be considered as the upper electrode and the upper electrode as the lower electrode by turning the memory cell upside down while remaining within the field of application of the memory cell according to the invention.

It should be noted that the memory according to an aspect of the invention is applicable to other lower electrode materials selected from the following materials: Ta, TaN, Cu, W, Pt, Au or Ag. In this case, the local zone includes, in addition to vanadium and oxygen, Ta (in the case of a Ta or TaN lower electrode), Cu (in the case of a Cu lower electrode), W (in the case of a W lower electrode), Pt (in the case of a Pt lower electrode), Au (in the case of an Au lower electrode) or Ag (in the case of an Ag lower electrode).

Similarly, the memory according to an aspect of the invention can be applied to any type of active layer made of conductive vanadium oxide. In other words, the active layer can be made of conductive V₂O₃ but also of conductive V₆O₁₃, of VO₂ in its metallic rutile phase or of V₂O₃₋₆: Cr (that is, sub-stoichiometric V₂O₃ substituted in Cr with respect to vanadium). More generally, all vanadium oxides of the conductive VnO₂ₙ-1 type (with n an integer greater than or equal to 2) have temperature-resistive transitions and become conductive above a certain temperature: they can therefore be applied to the memory according to an aspect of the invention in the case where this temperature is reached during the operation of the memory cell. Even more generally, all vanadium oxides made conductive by any possible methods (temperature, electric field, laser pulse, etc.) can be applied to the method according to an aspect of the invention.

In addition to the characteristics just discussed in the previous paragraphs, the memory cell according to an aspect of the invention may have one or more additional characteristics from among the following, considered individually or according to any technically possible combination:
the upper electrode is based on titanium nitride;
the local zone is not in contact with the second contact surface;
the thickness of the active layer is between 5 and 200 nm;
the local zone is in the shape of a dome whose cross-section parallel to the plane of the layers decreases from the first contact surface;
the titanium nitride-based lower electrode includes vanadium, titanium and oxygen in a zone located in proximity to the first contact surface. In this case, the local zone has, for example, a mushroom shape with a dome whose cross-section parallel to the plane of the layers decreases from the first contact surface;
the first contact surface has an area less than or equal to 9000 nm² and preferably less than or equal to 6000 nm²;
the first contact surface is equal to the upper surface of the lower electrode and strictly less than the total lower surface of the active layer;
the lower electrode has a rectangular parallelepiped shape of the ‘Wall’ type or an L shape;
the conductive vanadium oxide V₂O₃ is crystalline or partially crystalline;
the local zone is made of a crystalline or partially crystalline material.

Another aspect of the invention is a method for manufacturing a memory cell including the following steps of:
Making a lower electrode based on titanium nitride;
Depositing a layer made of vanadium oxide V₂O₃ having a first contact surface with the lower electrode;
Making an upper electrode;
the method including a step, referred to as the initialisation step, consisting in injecting a current through the stack formed by the lower electrode, the V₂O₃ layer and the upper electrode, the current density being chosen to create the local zone including vanadium, titanium and oxygen.

In addition to the characteristics just discussed in the previous paragraphs, the manufacturing method according to one or more embodiments of the invention may have one or more additional characteristics from among the following, considered individually or according to any technically possible combinations:
the method includes a heat treatment step during or after the deposition step until the vanadium oxide V₂O₃ layer is made conductive;
the layer deposited is made of amorphous vanadium oxide V₂O₃;
the current density of the initialisation step is greater than or equal to 50.10⁶ A/cm²;
depositing the layer made of vanadium oxide V₂O₃ is carried out using an ion beam deposition technique;
the method includes a step of cleaning the lower electrode by ion etching (Ar, Xe or Kr) in situ (that is, in the same equipment as the step of depositing V₂O₃, without venting) before the step of depositing V₂O₃;
making the upper electrode can be carried out in situ or after venting.

### BRIEF DESCRIPTION OF THE FIGURES

The figures are set forth by way of illustrating and in no way limiting purposes of the invention.

FIG. 1 schematically represents a 3 D view of the memory cell according to an embodiment of the invention.

FIG. 2 represents the behaviour during 1000 write (SET) and erase (RESET) cycles of a memory cell according to an embodiment of the invention.

FIG. 3 shows a dark-field STEM image of a memory cell before initialisation.

FIG. 4 shows a dark-field STEM image of a memory cell according to an embodiment of the invention.

FIG. 5, FIG. 6, FIG. 7, and FIG. 8 show energy dispersive X spectroscopy (EDX) and TEM microscopy analyses of a memory cell according to an embodiment of the invention.

FIG. 9, FIG. 10, FIG. 11, and FIG. 12, FIG. 13, FIG. 14, and FIG. 15 show results of write (SET) and erase (RESET) cycles for cells according to an embodiment of the invention with different contact surfaces and different active layer thicknesses.

FIG. 16 schematically illustrates the operation of a memory cell according to an embodiment of the invention.

FIG. 17 shows a dark-field STEM image and Electron Energy Loss Spectroscopy (EELS) analyses showing absence of oxygen and vanadium in the upper part of the lower electrode of the memory cell before initialisation.

FIG. 18 shows a dark-field STEM image and EELS analyses showing the presence of oxygen and vanadium in the upper part of the lower electrode of the memory cell according to an embodiment of the invention.

FIG. 19 shows a dark-field STEM image of a memory cell according to an embodiment of the invention.

FIG. 20 shows an energy dispersive X spectroscopy EDX and TEM microscopy analysis illustrating vanadium depletion of the localised zone of the memory cell according to an embodiment of the invention.

The invention and its different applications will be better understood upon reading the following description and examining the accompanying figures.

### DETAILED DESCRIPTION

Unless otherwise specified, a same element appearing in different figures has a unique reference.

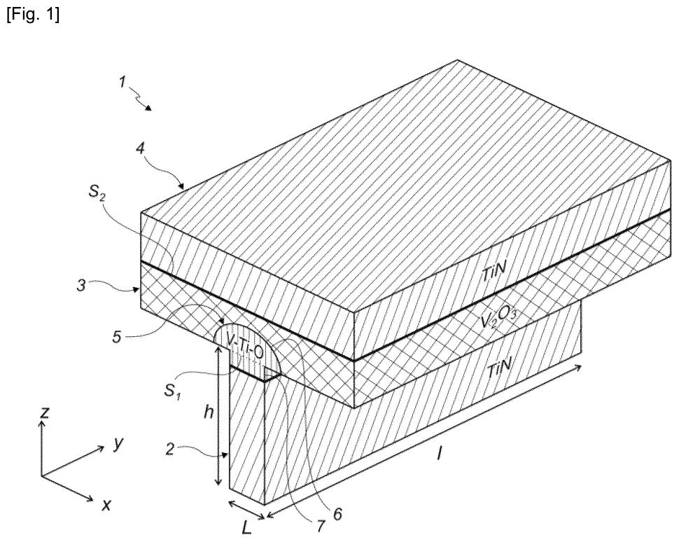

FIG. 1 schematically represents in three dimensions a memory cell 1 according to an embodiment of the invention in a reference frame Oxyz, the plane Oxy defining the plane of the layers, the axis Oz defining the direction of the height of the layers, the axis Oy defining the direction of the length of the layers and the axis Ox defining the direction of the width of the layers.

The memory cell 1 includes:
A TiN lower electrode 2;
A TiN upper electrode;
An active layer 3 mainly made of conductive vanadium oxide V₂O₃ and crystallised or partially crystallised but with a singular localised zone 5 including titanium, vanadium and oxygen which shall described below.

The upper surface of the active layer 3 is in contact with the lower surface of the upper electrode 4, along a contact surface S2.

The lower surface of the active layer 3 is in contact with the upper surface of the lower electrode 2, along a contact surface S1.

The lower electrode 2 has a ‘wall’ type architecture, that is, it forms a parallelepipedal wall of length 1, width L and height h: the area 1×L of the upper surface of the electrode is strictly less than the area of the lower surface of the active layer 3; in other words, the area of the contact surface S1 is equal to 1×L. The area of the contact surface S1 is strictly less than the area of the contact surface S2 (that is, the lower electrode 2 here has a width L much less than the width of the upper electrode 4 and a length 1 less than or equal to that of the upper electrode 4). It should be noted that the lower electrode 2 can also have other shapes such as an L shape with an upper first part identical to the wall set forth above and a lower second part of parallelepipedal shape parallel to the plane of the layers.

The active layer 3 of the memory cell 1 according to an embodiment of the invention can especially be made by depositing a crystallised or partially crystallised conductive V₂O₃ layer using an ion beam deposition IBD technique. The deposition involves the sputtering of a vanadium target by a beam of argon ions. The deposition chamber is vacuumized (5×10⁸ Torr) prior to deposition. During deposition, the partial pressure of oxygen is controlled and influences the degree of oxidation of the final material. Deposition takes place at room temperature and does not necessarily require heat treatment, thus making the method for obtaining the memory cell according to an embodiment of the invention compatible with CMOS back end integration. Even with crystallisation annealing, the latter remains below 450° C., which is the maximum temperature for CMOS back end integration.

According to another embodiment, after IBD deposition, V₂O₃ is insulating (resistivity in the order of a few ohms.cm to a few tens of ohms.cm) and is amorphous (no diffraction peaks detectable by XRD characterisation). Optionally, annealing at a temperature below 450° C. and, in an embodiment, greater than or equal to 280° C. is carried out in order to obtain a crystallised or partially crystallised conductive V₂O₃ material (that is, with a resistivity less than or equal to 0.1 ohm.cm). It should be noted that the annealing step can be carried out during the manufacture of the wall-type memory cell which implements some technological steps, such as the deposition of encapsulation dielectrics, at temperatures in the order of 300° C., temperatures at which the amorphous IBD V₂O₃ crystallises.

Making the titanium nitride-based upper and lower electrodes is performed according to techniques well known to those skilled in the art. At this stage, the active layer is exclusively made of crystallised or partially crystallised conductive V₂O₃, whereas it has been seen that the active layer 3 according to an embodiment of the invention includes a singular localised zone 5 including titanium, vanadium and oxygen. Conductive V₂O₃ could also be obtained by other deposition techniques such as PVD deposition. It is also possible to use crystallised conductive V₂O₃ in which part of the vanadium is substituted with chromium as long as the V₂O₃ remains conductive.

To obtain this singular localised zone 5, it is advisable to carry out an initialisation step through the stack formed by the two electrodes (the lower electrode having the shape of the wall 2) and the layer of crystallised or partially crystallised conductive V₂O₃. It is understood that at this stage, known as the pristine state (that is, blank state), the stack is in a low resistive LRS state since the V₂O₃ layer is conductive. The initialisation step consists in injecting a current with a high current density, preferably strictly greater than 50.10⁶ A/cm², by applying a positive voltage between the first and second electrodes (initialisation voltage). This step causes the stack to toggle from its pristine LRS state to a high resistive HRS state and cause the appearance of the localised zone 5 represented in FIG. 1. The appearance of this zone including titanium, oxygen and vanadium can be explained by the injection of a high density current at the contact surface S1 between the first electrode 2 and the active layer 3. The area of the upper surface I×L of the wall-shaped first electrode is chosen to be small enough to cause local heating at S1 and the zone in proximity to S1 (that is, above in the active zone 3 and below in the first electrode 2). Electrothermal simulations using the COMSOL tool show that the temperature reached at the interface between the lower wall electrode 2 and the active layer 3 can reach 2000° K: this local heating causes the creation of the zone 5 made of a V—Ti—O alloy including a first part 6 in the shape of a dome extending from the first contact surface S1 and rising inside the active layer 3 and a second part 7 located on the upper end of the lower electrode 2. In other words, zone 5 has the shape of a mushroom with its cap in the active zone 3 and its foot at the top of the lower electrode 2.

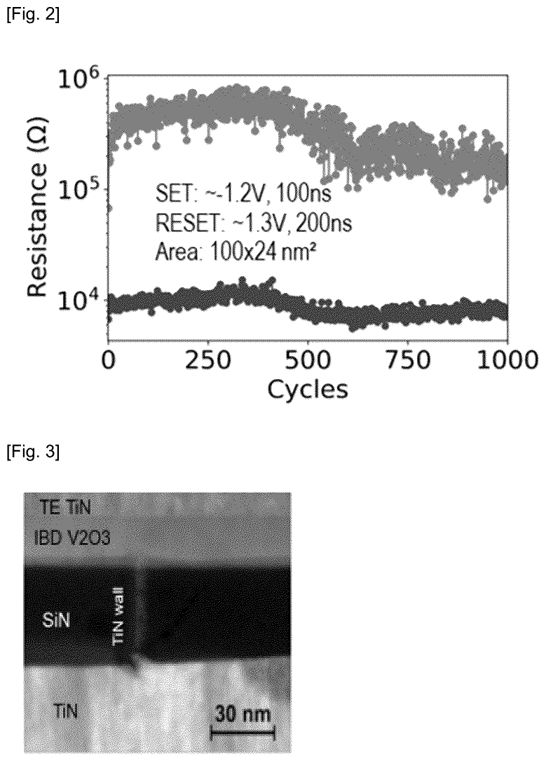

Once this initialisation operation has been carried out and the V—Ti—O-based zone 5 has been created, the memory cell 1 behaves as a bipolar type resistive memory cell. In other words, the application of a SET voltage pulse will make it possible to perform a SET operation and toggle to a low resistive LRS state. Then the application of a RESET voltage pulse of opposite sign to the SET voltage will make it possible to toggle to a high resistive HRS state. The memory cell has a non-volatile behaviour so that it retains the value of the resistance once the SET or RESET voltage is no longer applied. FIG. 2 shows the behaviour over 1000 write (SET) and erase (RESET) cycles of a memory cell according to an embodiment of the invention with a thickness of the active layer of 50 nm, a length 1 of the wall type lower electrode of 100 nm and a width L of 24 nm. The SET pulse is 1.2 V for 100 ns and the RESET pulse of opposite polarity to the SET pulse is 1.3 V for 200 ns. Good endurance performance (that is, over 1000 SET/RESET cycles) is observed for the memory cell according to an embodiment of the invention, which switches from an LRS resistance of a few kOhms to an HRS resistance in the order of a few hundred kOhms. The endurance results show a low dispersion of the resistive states compared with other types of resistive memory such as CBRAM or OxRAM. It is noted that the SET and RESET pulses have amplitudes of less than 2 V and durations of less than 1 μs.

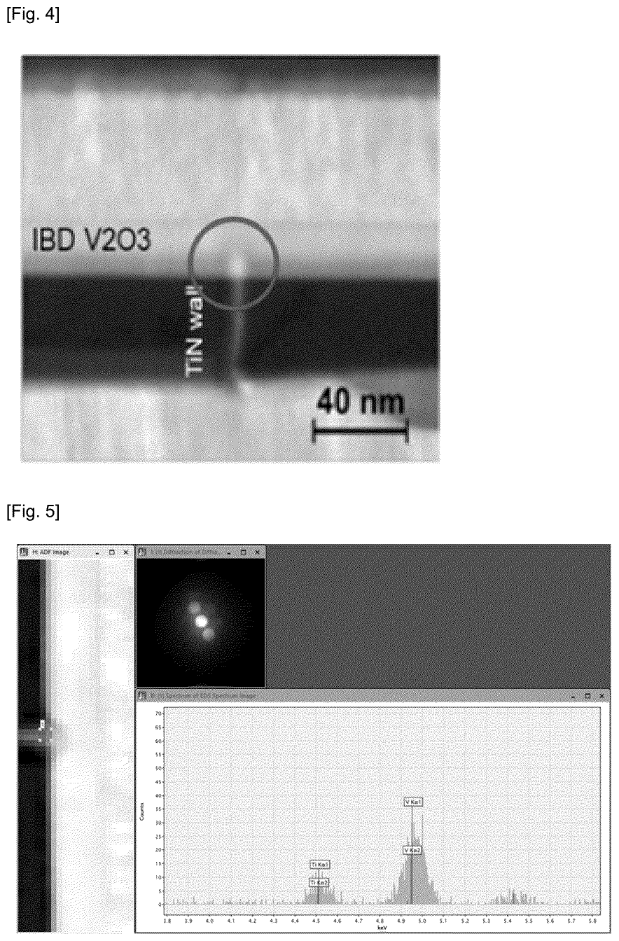

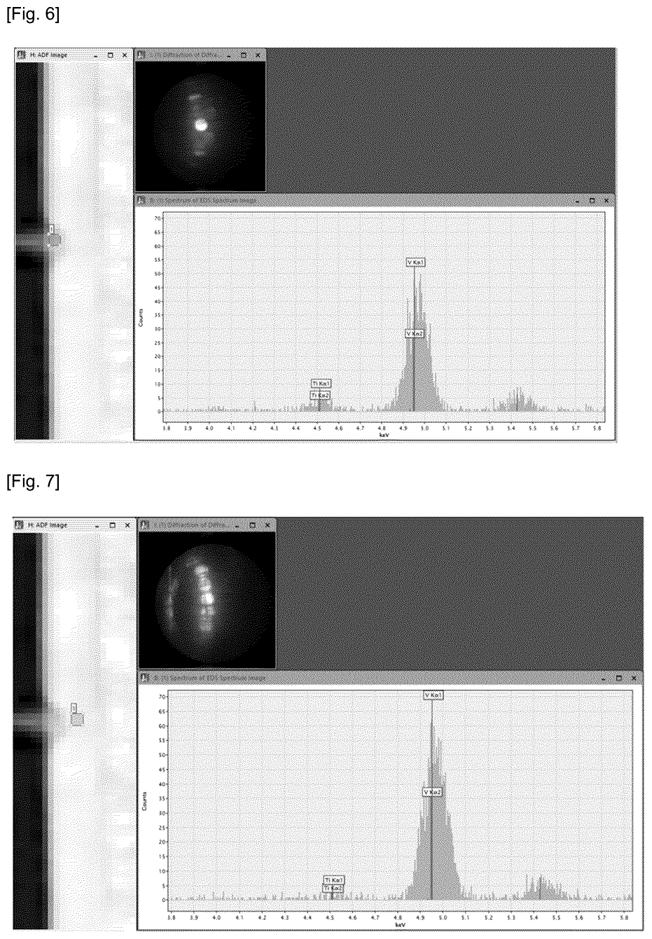

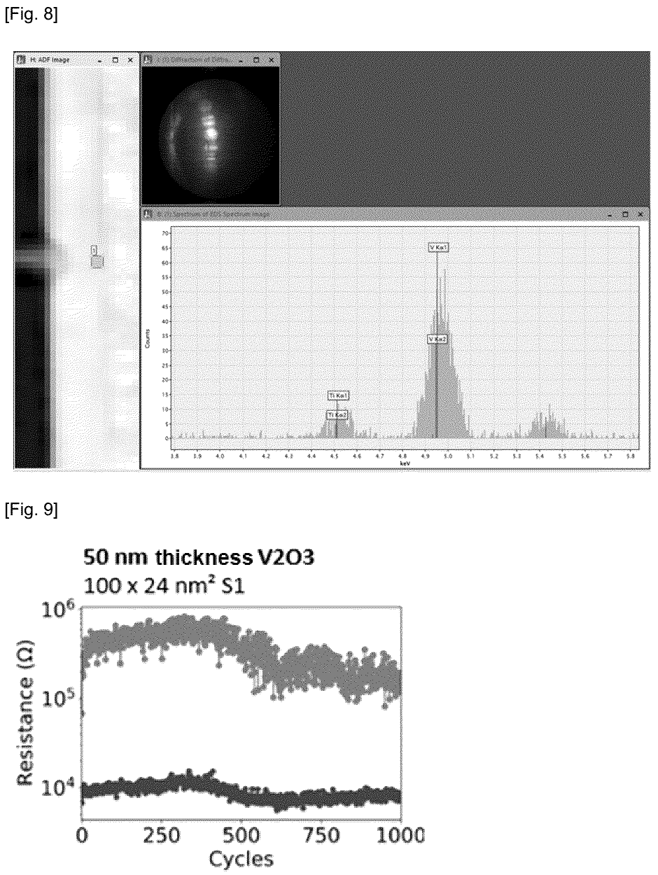

Highlighting the localised zone 5 has been carried out by Scanning Transmission Electron Microscopy (STEM) images illustrated in FIGS. 3 and 4. FIG. 3 shows a dark-field STEM image of a cell before initialisation and FIG. 4 shows a dark-field STEM image of a memory cell according to an embodiment of the invention after the initialisation step and 40 programming cycles. The circle represented in FIG. 4 surrounds the particular zone 5 in FIG. 1 created after the initialisation step, above the TiN wall lower electrode. This zone 5, not present on FIG. 3 before the initialisation step, is an altered zone a few nanometres thick with a high atomic density in the shape of a dome whose cross-section parallel to the plane of the layers decreases from the first contact surface. It is noticed that this zone 5 is located inside the conductive V₂O₃ active layer 3 and has a different atomic density to that of the conductive V₂O₃ part. It is also noted that this zone 5 starts from the contact surface between the active layer 3 and the lower TiN electrode 2 and then rises in the thickness of the active layer 3 without reaching the upper surface of the active layer 3, so that the zone 5 is not in contact with the upper electrode 4: the localised zone 5 remains present during the different programming cycles and can be seen as a zone in contact with the lower electrode 2 in a more overall conductive V₂O₃ zone. The fact that the memory cell according to an embodiment of the invention is in a high resistive state after the initialisation step indicates that the zone 5 is made of a high resistive material. Thus, the initialisation step induces a change in the composition of the conductive V₂O₃ material in this zone and the formation of a high resistive alloy based on vanadium, titanium and oxygen. This result is supported by literature data indicating high resistivities in the order of 105 Ohm.cm for TiO₂-V₂O₃-V₂O₅ alloys and, above all, by EDX (Energy Dispersive X-ray) spectroscopy analyses illustrated in FIGS. 5 to 8, which demonstrate the presence of titanium in this particular zone 5. FIGS. 5 to 8 each represent:
On the right part, a TEM (Transmission Electron Microscopy) image of the memory cell according to an embodiment of the invention;
On the top part, a diffraction pattern of the zone surrounded by the rectangle in the TEM image;
On the bottom part, the EDX spectrum of the zone surrounded by the rectangle in the TEM image.

The TEM and EDX analyses show the creation of a local zone in the shape of a dome 6 including vanadium, titanium and oxygen. The presence of vanadium and oxygen is not surprising given that this zone is located in a layer initially made of V₂O₃. On the other hand, the EDX analyses clearly show the presence of titanium in the first wall-type electrode and also in the local zone immediately above the first electrode and denoted as 5 in FIG. 1. It can be noticed that the amount of titanium is greater at the contact interface S1 between the active layer 3 and the lower electrode 2, then gradually decreases until it disappears in the active layer 3 which includes only V₂O₃ in its top part: this observation makes it possible to clearly identify the singular zone 5 which does not extend over the entire height of the active layer 3. The presence of titanium is again apparent at the upper electrode 4.

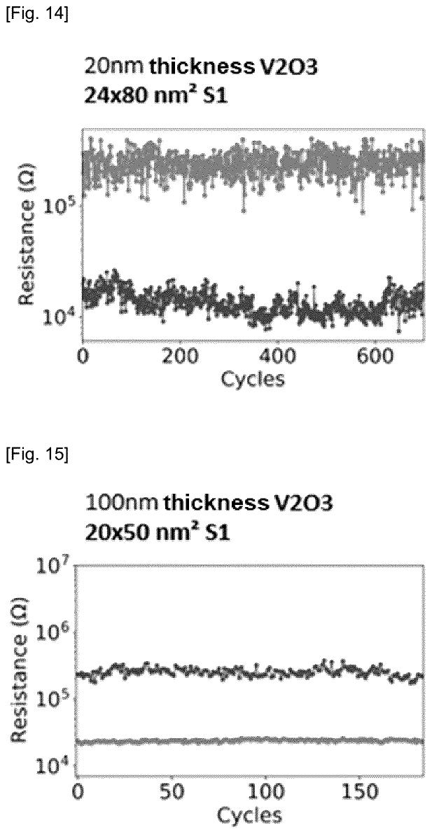

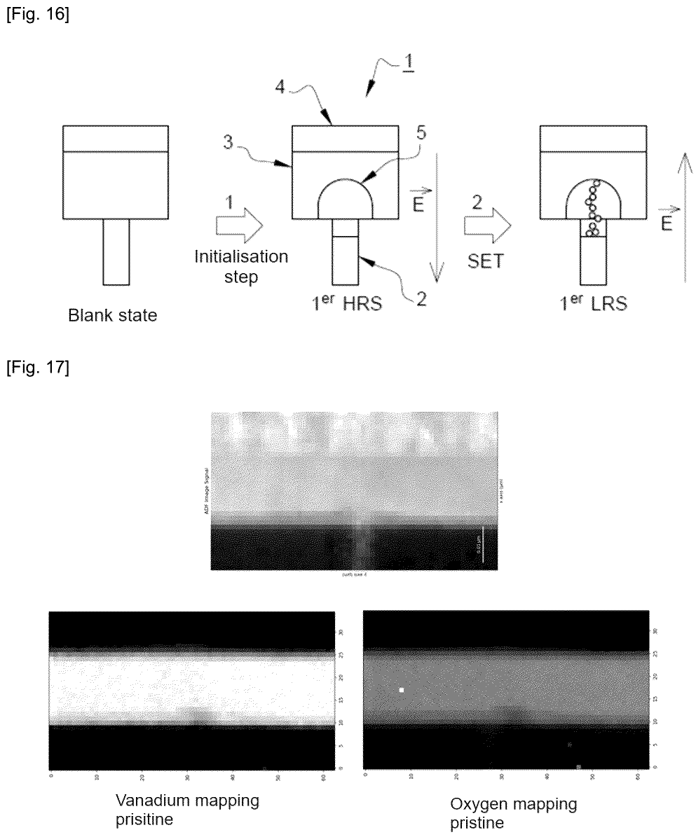

FIGS. 17 and 18 show EELS analyses by electron energy loss spectrometry illustrating the distribution of vanadium and oxygen respectively for a stack of a memory cell according to an embodiment of the invention before the initialisation step and for a memory cell according to an embodiment of the invention once formed. For each FIGS. 17 and 18, the top part shows a transmission electron microscopy image of the zone analysed: the lower electrode as well as the active layer can be seen. In FIG. 17, the EELS images of the non-initialised stack (bottom left for vanadium and bottom right for oxygen) show the presence of vanadium and oxygen only in the active layer. On the other hand, in FIG. 18, the EELS images of the memory cell according to an embodiment of the invention (bottom left for vanadium and bottom right for oxygen) show the presence of oxygen and vanadium, in addition to titanium, in the top part 7 of the lower electrode 2. Therefore, there is indeed a mushroom-shaped local zone 5 (dome 6 and upper part 7 of the lower electrode) including vanadium, titanium and oxygen.

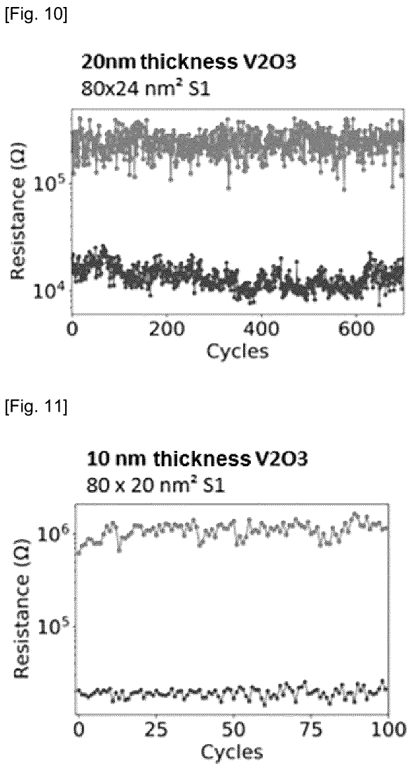

FIGS. 9 to 15 show cycling results for cells according to an embodiment of the invention with different contact surfaces S1 and different thicknesses of active layer 3. These results show that the thickness of the conductive V₂O₃ layer has little impact on the memory behaviour of the cell according to an embodiment of the invention: however, this thickness is, for example, between 5 and 200 nm and beneficially between 10 and 100 nm. The contact surface S1 (that is, corresponding to the upper surface of the wall lower electrode 2) is, in an embodiment, less than 6000 nm2.

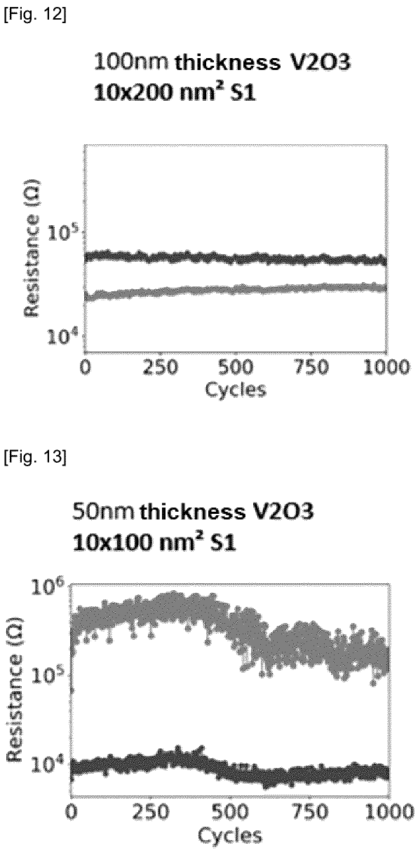

FIG. 16 schematically illustrates an explanation of the operating mode of the cell according to an embodiment of the invention. The left-hand side of the figure shows the stack before the initialisation step without the presence of the local high resistive zone 5: in this blank configuration, the stack is low resistive. After the initialisation step, for transitioning from a low resistive blank state to a high resistive HRS state, the memory cell according to invention 1 is created with the presence of the singular high resistive zone 5 especially including Ti, V and O. The resistive memory cell could then behave as a filament resistive memory with the singular zone 5 acting as a solid electrolyte. Thus, upon application of a positive potential to the lower electrode 2, mobile titanium-based ions would move from the lower electrode 2 under the effect of the electric field applied to the electrodes resulting in the growth of a titanium metal filament within the singular Ti, V and O-based zone 5. As the rest of the active layer 3 is made of metal oxide, the memory cell according to an embodiment of the invention then transitions into a low resistive LRS state. The transition to the high resistive state HRS consists in applying a negative voltage to the lower electrode 2, resulting in total or partial dissolution of the conductive filament.

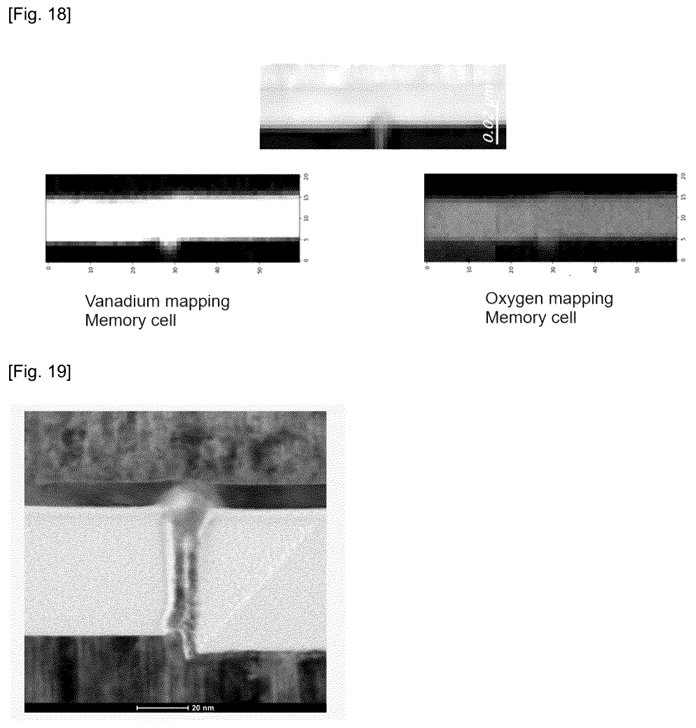

It should be noted that, according to another embodiment, the memory cell according to an embodiment of the invention is made with a TiN/V₂O₃/TiN type stack comprising a 10 nm thick active layer of V₂O₃ which has not been annealed. After initialisation, the local zone is formed by being in contact with both the surface S1 of the lower electrode and the surface S2 of the upper electrode. This is illustrated in FIG. 19, which shows a STEM Scanning Transmission Electron Microscopy image of the localised zone 5, the zone extending from the surface of the lower electrode to the surface of the upper electrode.

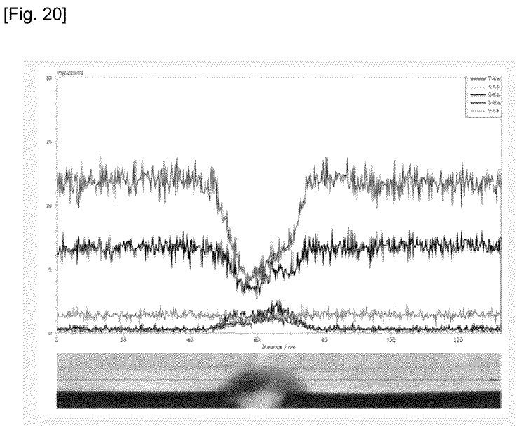

The localised zone or dome further comprises a volume vanadium atom depletion greater than or equal to 20% (that is, in the order of 40% or even more) relative to the vanadium atoms present in volume in the rest of the vanadium oxide active layer. The presence of voids has also been observed. This vanadium atom depletion is illustrated in FIG. 20 corresponding to an initialised spectrum showing vanadium depletion at the localised zone (the highest spectrum curve of FIG. 20 shows the vanadium depletion).

Other stacks of the memory cell according to an embodiment of the invention have been made with a thickness e of the active layer, a length 1 and a width L of the wall type lower electrode:
TiN upper electrode/non-stoichiometric crystalline V₂O₃ active layer with 10% Cr substituted with respect to vanadium (10 atomic % Cr with respect to V+Cr or 4 atomic % Cr with respect to V+Cr+O) having a thickness e equal to 5 nm, 10 nm or 20 nm respectively/TiN wall-type lower electrode (with a width L in the order of 15 nm and a length 1 varying from 40 nm to 300 nm).
TiN upper electrode/crystalline V₂O₃ active layer having a thickness of 20 nm/TiN lower electrode
TiN upper electrode/crystalline V₂O₃ active layer having a thickness e of 50 nm/TiN wall-type lower electrode (with a width L in the order of 10 nm and a length 1 varying from 40 nm to 300 nm)
TiN upper electrode/amorphous V₂O₃ active layer having a thickness e of 10 nm/TiN wall type lower electrode (with a width L in the order of 10 nm and a length 1 varying from 40 nm to 300 nm).

It will be appreciated that the various embodiments and aspects of the inventions described previously are combinable according to any technically permissible combinations. For example, various aspects of the present disclosure may be used alone, in combination, or in a variety of arrangements not specifically described in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Having described above several aspects of at least one embodiment, it is to be appreciated various alterations, modifications, and improvements will readily occur to those skilled in the art. Such alterations, modifications, and improvements are intended to be object of this disclosure. Accordingly, the foregoing description and drawings are by way of example only.

1. A resistive memory cell comprising:
a lower electrode based on one of the following materials: titanium nitride TiN, tantalum nitride TaN, tantalum Ta, copper Cu, tungsten W, platinum Pt, gold Au or silver Ag;
an upper electrode, and
an active layer having a first contact surface with the lower electrode and a second contact surface with the upper electrode, said active layer including a local zone, said local zone being made of a material including vanadium, oxygen and Ti if the material of the lower electrode is TiN or Ta if the material of the lower electrode is TaN or Ta, or Cu if the material of the lower electrode is Cu, or W if the material of the lower electrode is W, or Pt if the material of the lower electrode is Pt, or Au if the material of the lower electrode is Au, or Ag if the material of the lower electrode is Ag, said local zone extending from the first contact surface, a rest of the active layer being made of conductive vanadium oxide.

2. The resistive memory cell according to claim 1, wherein the upper electrode is based on titanium nitride.

3. The resistive memory cell according to claim 1, wherein said local zone is not in contact with the second contact surface.

4. The resistive memory cell according to claim 1, wherein said local zone is in contact with the second contact surface.

5. The resistive memory cell according to claim 1, wherein said local zone has a volume vanadium atom depletion greater than or equal to 20% relative to the rest of the active layer.

6. The resistive memory cell according to claim 1, wherein a thickness of the active layer is between 5 and 200 nm.

7. The resistive memory cell according to claim 6, wherein the thickness of the active layer is between 10 and 100 nm.

8. The resistive memory cell according to claim 1, wherein the local zone has a shape of a dome whose cross-section parallel to a plane of the layers decreases from the first contact surface.

9. The resistive memory cell according to claim 1, wherein the titanium nitride-based lower electrode includes vanadium, titanium and oxygen in a zone located in proximity to the first contact surface.

10. The resistive memory cell according to claim 1, wherein the first contact surface has an area of less than or equal to 9000 nm².

11. The resistive memory cell according to claim 10, wherein the first contact surface has an area less than or equal to 6000 m².

12. The resistive memory cell according to claim 1, wherein the first contact surface is equal to the upper surface of the lower electrode and is strictly less than the total lower surface of the active layer.

13. The resistive memory cell according to claim 1, wherein the lower electrode has a rectangular parallelepiped shape of the ‘Wall’ type or an L shape.

14. The resistive memory cell according to claim 1, wherein the conductive vanadium oxide is crystalline or partially crystalline.

15. The resistive memory cell according to claim 1, wherein the local zone is made of a crystalline or partially crystalline material.

16. A method for manufacturing a resistive memory cell according to claim 1, comprising:
making a lower electrode based on one of the following materials: titanium nitride TiN, tantalum nitride TaN, tantalum Ta, copper Cu, tungsten W, platinum Pt, gold Au or silver Ag;
depositing a layer made of vanadium oxide having a first contact surface with the lower electrode;
Making an upper electrode;
said method including an initialisation step consisting in injecting a current through a stack formed by the lower electrode, the vanadium oxide layer and the upper electrode, the current density being chosen to create said local zone including vanadium, oxygen and Ti if the material of the lower electrode is TiN or Ta if the material of the lower electrode is TaN or Ta, or Cu if the material of the lower electrode is Cu, or W if the material of the lower electrode is W, or Pt if the material of the lower electrode is Pt, or Au if the material of the lower electrode is Au, or Ag if the material of the lower electrode is Ag.

17. The method for manufacturing a memory cell according to claim 16, further comprising a heat treatment step during or after said depositing until said vanadium oxide layer is made conductive.

18. The method for manufacturing a memory cell according to 16, wherein the current density of the initialisation step is greater than or equal to 50.10⁶ A/cm².

19. The method for manufacturing a memory cell according to claim 16, wherein said depositing of the layer made of vanadium oxide is carried out by an ion beam deposition technique.
